(19) United States
(12) Patent Application Publication
(10) Pub. No.: US 2011/0247688 A1
(43) Pub. Date: Oct. 13, 2011

(54) FRONT ELECTRODE FOR SOLAR CELL HAVING MINIMIZED POWER LOSS AND SOLAR CELL CONTAINING THE SAME

(75) Inventors: Seokhyun Yoon, Daejeon (KR); Inseok Hwang, Daejeon (KR); Seung Wook Kim, Gyeonggi-do (KR)

(73) Assignee: LG CHEM, LTD., Seoul (KR)

(21) Appl. No.: 13/063,602

(22) PCT Filed: Sep. 9, 2009
(86) PCT No.: PCT/KR2009/005096

§ 371 Date: Jun. 28, 2011

(30) Foreign Application Priority Data
Sep. 12, 2008 (KR) 10-2008-0090073

(51) Int. Cl. H01L 31/0224

(52) U.S. Cl. 136/256; 438/98; 257/E31.124

(57) ABSTRACT

Disclosed herein is a front electrode for solar cells, wherein the front electrode is configured in a structure in which a pattern including a plurality of grid electrodes arranged in parallel and at least one current collection electrode intersecting the grid electrodes is formed on a semiconductor substrate, current introduced to the grid electrodes is moved to and collected in the current collection electrode, and the width of each of the grid electrodes is increased toward the current collection electrode.

### TECHNICAL FIELD

The present invention relates to a front electrode for solar cells having minimized power loss and a solar cell including the same, and, more particularly, to a front electrode for solar cells, wherein the front electrode is configured in a structure in which a pattern including a plurality of grid electrodes arranged in parallel and at least one current collection electrode intersecting the grid electrodes is formed on a semiconductor substrate, current introduced to the grid electrodes is moved to and collected in the current collection electrode, and the width of each of the grid electrodes is increased toward the current collection electrode.

### BACKGROUND ART

In recent years, with increased concerns about environmental problems and depletion of nonrenewable energy sources, solar cells have drawn attention as an alternative energy source which uses abundant energy resources, is free of problems associated with pollution and has high energy efficiency.

Solar cells may be classified into solar thermal cells which generate steam energy necessary to rotate a turbine using solar heat and photovoltaic solar cells which convert photons into electric energy using properties of semiconductors. In particular, a great deal of research has focused on photovoltaic solar cells which absorb light, generating electrons and holes and thereby converting light energy into electric energy.

FIG. 1 is a view typically illustrating the structure of such a photovoltaic solar cell (hereinafter, simply referred to as a “solar cell”). Referring to FIG. 1, the solar cell includes a first conduction type semiconductor layer 22 and a second conduction type semiconductor layer 23, which is opposite to the conduction type of the first conduction type semiconductor layer 22, formed on first conduction type semiconductor layer 22. A p/n junction is achieved at the interface between the first conduction type semiconductor layer 22 and the second conduction type semiconductor layer 23. A rear electrode 21 is disposed in contact with at least a portion of the first conduction type semiconductor layer 22, and a front electrode 11 is disposed in contact with at least a portion of the second conduction type semiconductor layer 23. According to circumstances, an anti-reflective film 24 to disturb light reflection may be formed at the top of the second conduction type semiconductor layer 23.

A p-type silicon substrate is usually used as the first conduction type semiconductor layer 22, and an n-type emitter layer is used as the second conduction type semiconductor layer 23. Also, the front electrode 11 is usually formed at the top of the emitter layer 23 using a silver (Ag) pattern, and the rear electrode 21 is usually formed at the bottom of the semiconductor layer 22 using an aluminum (Al) layer. The front electrode 11 and the rear electrode 21 are generally formed using a screen printing method. The front electrode generally includes two current collection electrodes (also referred to as ‘bus bars’) having a large width and grid electrodes (also referred to as ‘fingers’) having a small width of approximately 150 μm.

In the solar cell having the above structure, when solar light is incident on the front electrode 11, free electrons are generated. The electrons move to the n-type semiconductor layer 23 according to a p/n conjunction principle. Such movement of the electrons generates current.

The performance of the solar cell which directly converts light energy into electric energy is expressed by a ratio of electric energy output from the solar cell to solar energy incident on the solar cell. This ratio indicates a performance index of the solar cell and is generally referred to as “energy conversion efficiency,” or simply “conversion efficiency.” Theoretically, conversion efficiency is limited by a material constituting a solar cell and is controlled according to matching of a spectrum of solar light energy and a sensitivity spectrum of a solar cell. For example, a single crystal silicon solar cell has a conversion efficiency of approximately 30 to 35%, a noncrystalline silicon solar cell has a conversion efficiency of approximately 25%, and a compound semiconductor solar cell has a conversion efficiency of approximately 20 to 40%. On the present laboratory level, however, a solar cell has a conversion efficiency of approximately 25%.

Loss may include loss caused by light reflected from a surface, loss caused by recombination of a carrier at the surface or an electrode interface, loss caused by recombination of the carrier in a solar cell, and loss caused by internal resistance of the solar cell.

Power loss caused by electrodes may include resistance loss caused by movement of light current at an n-type semiconductor layer, loss caused by contact resistance between the n-type semiconductor layer and grid electrodes, resistance loss caused by photoelectric current flowing in the grid electrodes, and loss caused by an area covered by the grid electrodes.

Consequently, there is a high necessity for technology that is capable of minimizing power loss caused by such electrodes and maximizing light absorption, thereby providing a solar cell exhibiting high efficiency.

### DISCLOSURE

### Technical Problem

Therefore, the present invention has been made to solve the above problems, and other technical problems that have yet to be resolved.

Specifically, it is an object of the present invention to provide a front electrode for solar cells wherein the width of grid electrodes is adjusted to minimize power loss caused by the electrodes and maximize light absorption.

As a result of a variety of studies and experiments on a front electrode for solar cells, the inventors of the present application have found that, when the front electrode is configured so that the width of grid electrodes at a current collection electrode side is relatively large, electrode loss of the front electrode according to the present invention is much less than that of a conventional front electrode. The present invention has been completed based on these findings.

### Technical Solution

In accordance with one aspect of the present invention, the above and other objects can be accomplished by the provision of a front electrode for solar cells, wherein the front electrode is configured in a structure in which a pattern including a plurality of grid electrodes arranged in parallel and at least one current collection electrode intersecting the grid electrodes is formed on a semiconductor substrate, current introduced to the grid electrodes is moved to and collected in the current collection electrode, and the width of each of the grid electrodes is increased toward the current collection electrode.

As shown in FIG. 5, conventional grid electrodes have a very large and uniform width of approximately 120 to 150 μm with the result that the area of regions (shadows) covered by the grid electrodes is large, resulting in high electrode loss. The inventors of the present application have considered a relationship between a loss of the grid electrodes and the size of the grid electrodes and the current collection electrode so as to develop a structure that is capable of minimizing a loss caused by the grid electrodes.

As previously discussed, electrode loss includes □ a loss (loss I) caused when current flows in the n-type semiconductor layer, □ loss (loss II) caused when the current flows from the n-type semiconductor layer to the grid electrodes, □ loss (loss III) caused when the current flows in the grid electrodes, and □ loss (loss IV) caused by an area covered by the grid electrodes. The loss may be calculated as follows with reference to FIG. 2.

Loss I=˜b²˜n⁻²×Rₛ

Loss II=˜b×ρ_{c}^{1/2}˜n⁻¹×ρ_{c}^{1/2}

Loss III=˜(Lₐ²×b)/(tₐ×Wₐ)˜Lₐ²×n⁻¹×Wₐ⁻²

Loss IV=˜Wₐ×n

(In the above expressions, b indicates the intervals of the grid electrodes, n indicates the number of the grid electrodes, ρ_{c} indicates contact specific resistance between the grid electrodes and the n-type semiconductor layer, Lₐ indicates the length of the front electrode, tₐ indicates the thickness (height) of the grid electrodes, and Wₐ indicates the width of the grid electrodes.)

From the above expressions, it can be seen that there are pairs of (n, Lₐ, Wₐ) in which the sum of the number (n) of the grid electrodes, the width (Wₐ) of the grid electrodes and the length (Lₐ) of the front electrode is minimized.

That is, as the width of the grid electrodes increases, the area of the shadows increases with the result that loss IV (hereinafter, also referred to as ‘shadow loss’ according to circumstances) increases, and therefore, light absorption is reduced. On the other hand, when the width of the grid electrodes is excessively small, electrode resistance increases with the result that loss III increases.

Meanwhile, since the amount of current flowing in the grid electrodes increases in an integral mode based on the length of the grid electrodes, it may be advantageous for the width of the grid electrodes to be small. When the length of the grid electrodes is equal to or greater than a predetermined length, however, it is preferable for the width of the grid electrodes to be small in consideration of resistance.

According to the present invention, therefore, the grid electrodes are configured to have a structure in which the width of the grid electrodes is increased toward the current collection electrode at which the amount of current increases. Also, it is preferable for the grid electrodes to be at right angles to the current collection electrode in consideration of efficiency per unit area.

The width of each of the grid electrodes may be increased so that the width of each of the grid electrodes at one end thereof adjacent to the current collection electrode is preferably 50 to 500%, more preferably 200 to 500%, greater than the width of each of the grid electrodes at the other end thereof distant from the current collection electrode.

The width of each of the grid electrodes may be variously increased toward the current collection electrode. As an example, the width of each of the grid electrodes may be continuously increased in inverse proportion to the distance from the current collection electrode.

The width of each of the grid electrodes may be continuously increased, for example, in a straight structure having the shape of a linear function or in a curved structure having the shape of a quadratic function.

As another example, the width of each of the grid electrodes may be discontinuously increased in inverse proportion to the distance from the current collection electrode.

The width of each of the grid electrodes may be discontinuously increased, for example, in a stair type structure or in a basin type structure.

In a preferred example, the pattern may include a first pattern part at which the width of each of the grid electrodes is 150 μm or less and a second pattern part at which the width of each of the grid electrodes is less than that of each of the grid electrodes at the first pattern part.

In a case in which the front electrode is configured to have such a combination type structure having a first pattern part at which the width of each of the grid electrodes is relatively large and a second pattern part at which the width of each of the grid electrodes is relatively small as described above, it is possible to effectively deal with the amount of current cumulatively increasing based on the length of the grid electrodes, thereby minimizing loss due to the increase in current resistance.

To this end, it is preferable to form the first pattern part at the grid electrodes located at the current collection electrode at which the amount of current increases so that the first pattern part has a predetermined length. Also, it is preferable for the grid electrodes to be at right angles to the current collection electrode in consideration of efficiency per unit area. Preferably, the width of the current collection electrode is approximately 1.5 to 3 mm, and two current collection electrodes are provided so that the current collection electrodes are spaced apart from each other by a predetermined distance.

In a preferred example, the second pattern part may be configured to have a structure in which two or more grid electrodes are joined to each other. As a result, the grid electrodes, having the relatively small width, of the second pattern part are connected to the grid electrodes of the first pattern part while the grid electrodes of the second pattern part are joined to each other, and therefore, it is possible to lower power loss caused during movement of current between the first pattern part and the second pattern part to a negligible level.

The structure in which the grid electrodes are joined to each other at the second pattern part may be a dendrite structure in which end connection is achieved between the grid electrodes of the first pattern part and the grid electrodes of the second pattern part. Hereinafter, the electrodes to interconnect the grid electrodes of the first pattern part and the grid electrodes of the second pattern part will be referred to as dendrite electrodes.

It is preferable for the width of the grid electrodes at the first pattern part and the second pattern part to be adjusted so that the increase of resistance due to current accumulation is minimized while shadow loss due to the grid electrodes is minimized.

The second pattern part is a portion to which current is introduced, and therefore, current accumulation is low. In order to minimize the shadow loss, therefore, it is preferable for the grid electrodes to have a relatively small width. If the width of the grid electrodes is excessively small, however, it is difficult to form the grid electrodes and, in addition, resistance increases.

Also, the first pattern part is a portion from which current is discharged to the current collection electrode (also functioning as a current introduction portion according to circumstances). In order to minimize the increase of resistance due to current accumulation, therefore, it is preferable for the grid electrodes to have a relatively large width. If the width of the grid electrodes is excessively large, however, shadow loss is caused and materials are wasted.

In consideration of the above matters, therefore, the width of each of the dendrite electrodes may be one to two times, preferably 1 to 1.5 times, that of each of the grid electrodes of the second pattern part.

Also, the width of each of the grid electrodes of the first pattern part may be 1.1 to 15 times, preferably 3 to 5 times, that of each of the grid electrodes of the second pattern part within a range greater than that of each of the dendrite electrodes.

In a preferred example, the width of each of the grid electrodes of the second pattern part may be 10 to 60 μm, preferably 10 to 40 μm, and the width of each of the grid electrodes of the first pattern part may be 50 to 150 μm, preferably 60 to 100 μm, within a range greater than that of each of the grid electrodes of the second pattern part.

In a case in which the dendrite electrodes are formed, the width of each of the dendrite electrodes may be equal to that of each of the grid electrodes of the second pattern part or 10 to 60 μm, preferably 10 to 50 μm, within a range greater than that of each of the grid electrodes of the second pattern part.

Meanwhile, if the intervals of the grid electrodes are large, movement distance of current from the n-type semiconductor layer to the grid electrodes is increased, resulting in current loss. If the intervals of the grid electrodes are excessively small, on the other hand, shadow loss is increased.

Since the width of each of the grid electrodes at the second part is less than that of each of the conventional grid electrodes, shadow loss is not increased even when the intervals of the grid electrodes, which are approximately 2.5 to 3 mm in the conventional art, are reduced. Furthermore, the movement distance of current is decreased, thereby further improving efficiency. Since the grid electrodes of the first pattern part have a greater width than those of the second pattern part, on the other hand, it is preferable to set the intervals of the grid electrodes at the first pattern part so that the intervals of the grid electrodes at the first pattern part are not much less than those of the grid electrodes at the second pattern part in order to minimize shadow loss. For example, the intervals of the grid electrodes of the first pattern part may be 0.7 to 6 times, preferably 1 to 3 times, those of the grid electrodes of the second pattern part.

In a preferred example, the intervals of the grid electrodes of the second pattern part may be 0.5 to 2 mm, and the intervals of the grid electrodes of the first pattern part may be equal to those of grid electrodes of the second pattern part or 1.5 to 3 mm within a range greater than those of the grid electrodes of the second pattern part.

The dendrite electrodes are preferably inclined at an angle of 30 to 70 degrees to the longitudinal direction of the grid electrodes.

Also, if the length of the second pattern part is greater than 70% the total length of the grid electrodes or the length of the first pattern part is less than 30% the total length of the grid electrodes, current resistance is excessively increased. On the other hand, if the length of the second pattern part is less than 10% the total length of the grid electrodes or the length of the first pattern part is greater than 90% the total length of the grid electrodes, shadow loss is increased.

Consequently, the length of each of the grid electrodes of the second pattern part is preferably 10 to 70% the total length of each of the grid electrodes. Also, it is preferable for the length of each of the grid electrodes of the first pattern part to be 30 to 90% the total length of each of the grid electrodes. If the length of each of the dendrite electrodes is large, the length of each of the grid electrodes is excessively increased. Consequently, the length of each of the dendrite electrodes is preferably 0 to 10% the total length of each of the grid electrodes.

The semiconductor substrate may include an n-type semiconductor layer formed of crystalline silicon. According to circumstances, various kinds of layers may be added to the semiconductor substrate. For example, an anti-reflective film may be applied to the top of a dopant layer of an N+ semiconductor layer. Silicon nitride or silicon oxide may be used as the anti-reflective film.

Also, it is preferable to increase the resistance of the n-type semiconductor layer in order to reduce surface recombination velocity of photoelectric current. The resistance of the n-type semiconductor layer may be 50Ω or more, preferably 100Ω or more.

In accordance with another aspect of the present invention, there is provided a solar cell including the front electrode as described above.

In the solar cell according to the present invention, the structure of the grid electrodes is optimized with the result that the solar cell has an electrode loss of 1.3 mW/cm² or less. Consequently, the solar cell according to the present invention has an advantage in that conversion efficiency is very high.

The solar cell may be formed of a bulk type material. Preferably, the solar cell is formed of crystalline silicon in consideration of efficiency. The structure and manufacturing method of the solar cell are well known in the art to which the present invention pertains, and therefore, a detailed description thereof will not be given.

In accordance with a further aspect of the present invention, there is provided a method of manufacturing a front electrode for solar cells. Conventional front electrodes are manufactured using a screen printing method. In the screen printing method, ink is pushed between screen masks to print the front electrodes. The screen printing method has a precision of approximately 100 μm, and therefore, it is not possible to achieve a pattern of less than 100 μm using the screen printing method, with the result that electrode loss is high. Also, ink is pushed through squeezing with the result that the screen printing method is not suitable for a continuous process.

In order to solve such problems, upon forming a pattern including a plurality of grid electrodes arranged in parallel and a current collection electrode intersecting the grid electrodes on a semiconductor substrate, the manufacturing method according to the present invention includes printing paste on a semiconductor substrate using a gravure printing method or an offset printing method so that the grid electrodes have a width of 100 μm or less and (b) heating and/or pressurizing the paste to harden the paste.

When the front electrode is formed using the gravure printing method or the offset printing method as described above, it is possible to easily form a micrometer scale pattern and to form the pattern through a continuous process, thereby greatly improving process efficiency.

As a concrete example, the offset printing method may include (i) preparing a printing substrate having grooves formed in a predetermined pattern corresponding to that of the front electrode, (ii) filling the grooves formed at the printing substrate with paste for electrode formation, (iii) rotating a printing roll on the printing substrate to transfer the paste placed in the grooves to the printing roll, and (iv) rotating the printing roll on a semiconductor substrate to transfer the paste from the printing roll to the semiconductor substrate.

The offset printing method has a patterning precision of approximately 10 to 20 μm, and the thickness of a pattern formed using the offset printing method is merely several μm. Consequently, the offset printing method has an advantage of forming a pattern having a sub-micrometer size. Also, in the offset printing method, the paste is transferred to the substrate using the printing roll. Consequently, it is possible to form a pattern through a single transfer process using a printing roll having a size corresponding to the area of the substrate even when the area of the substrate is large.

As another example, the gravure printing method may include (i) preparing a blanket cylinder having grooves formed in a predetermined pattern corresponding to that of the front electrode, (ii) filling the grooves formed at the blanket cylinder with paste for electrode formation, and (iii) rotating the blanket cylinder on a semiconductor substrate to transfer the paste from the blanket cylinder to the semiconductor substrate.

It is also possible to print a pattern having a sub-micrometer size using the gravure printing method. Consequently, the gravure printing method has an advantage of suitably forming a micrometer scale pattern and of simultaneously patterning a large area in the same manner as the offset printing method.

In the method of manufacturing the front electrode according to the present invention, the paste contains a material used to form the grid electrodes and the current collection electrode constituting the front electrode. Preferably, the paste contains silver (Ag) powder.

Meanwhile, the step of curing the paste may include preliminarily drying the paste at a temperature of 150 to 200° C., removing a binder at a temperature of 400 to 5200° C., and sintering the paste at a temperature of 750 to 850° C. The total time necessary to cure the paste may be 5 to 10 minutes.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a partial perspective view illustrating a conventional solar cell;

FIG. 2 is a typical view illustrating a front electrode for solar cells;

FIG. 3 is a partial plan view illustrating a second type front electrode according to an embodiment of the present invention;

FIG. 4 is a partial plan view illustrating a second type front electrode according to another embodiment of the present invention;

FIG. 5 is a partial plan view illustrating a conventional front electrode;

FIG. 6 is a typical view illustrating a process of forming a pattern using an offset printing method according to an embodiment of the present invention;

FIG. 7 is a partial perspective view illustrating a solar cell having the front electrode of FIG. 3;

FIG. 8 is a plan view of the solar cell having the front electrode of FIG. 3; and

FIGS. 9 and 10 are graphs illustrating power loss according to experimental examples of the present invention.

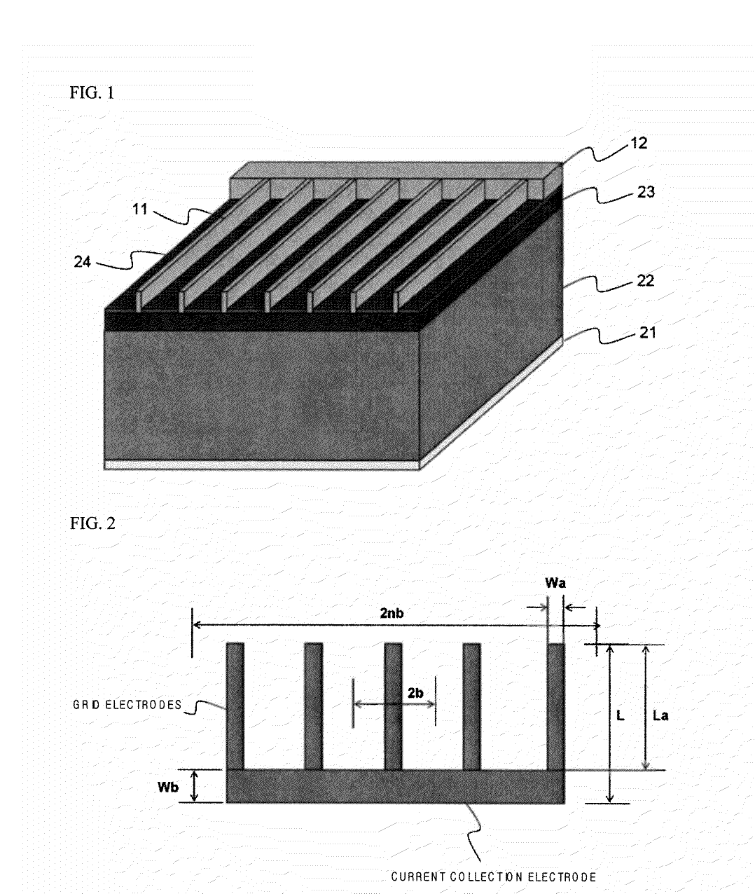

<Description of Main Reference Numerals of the Drawings>

| | |
|---|---|
| 11, 110: Grid electrodes | 12, 120: Current collection electrodes |
| 21, 201: Rear electrodes | 22, 202: P-type semiconductor layers |
| 23, 203: n-type semiconductor | 24, 204: Anti-reflective films |
| layers | |

### BEST MODE

Now, preferred embodiments of the present invention will be described in detail with reference to the accompanying drawings. It should be noted, however, that the scope of the present invention is not limited by the illustrated embodiments.

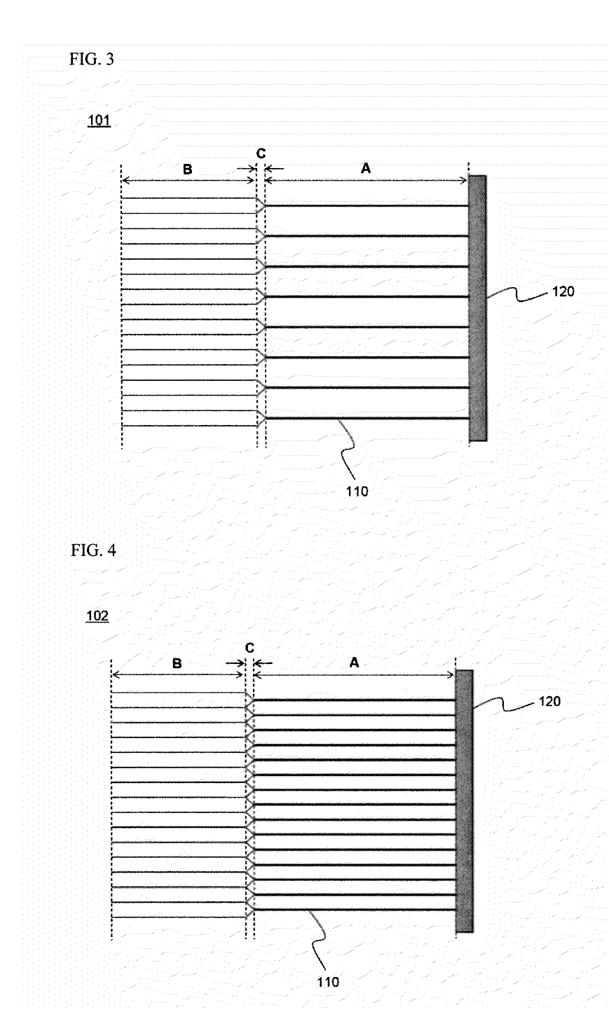

FIGS. 3 and 4 are partial plan views typically illustrating front electrodes according to embodiments of the present invention.

Referring to these drawings, each grid electrode 110 includes a first pattern part A adjacent to a current collection electrode 120, a second pattern part B distant from the current collection electrode 120, and a dendrite electrode C located between the first pattern part A and the second pattern part B. The first pattern part A. At the first pattern part A, grid electrodes each having a relatively large width are arranged at large intervals. At the second pattern part B, on the other hand, grid electrodes each having a relatively small width are arranged at small intervals.

In the above structure, the amount of current introduced is maximized by the second pattern part B, whereas current resistance and shadow loss are minimized by the first pattern part A.

At the front electrode shown in FIG. 3, every two grid electrodes of the second pattern part are joined to each other via each dendrite electrode C. At the front electrode shown in FIG. 4, all grid electrodes of the second pattern part are joined to each other via the corresponding dendrite electrodes C. For the front electrode of FIG. 4, the grid electrodes at the first pattern part are arranged at relatively small intervals. In consideration of a shadow loss, therefore, the grid electrodes may have a smaller width than the grid electrodes at the first pattern part of FIG. 3.

FIG. 6 is a typical view illustrating a process of manufacturing a front electrode using an offset printing method according to an embodiment of the present invention.

Referring to FIG. 6, first, grooves 301 having a shape corresponding to a pattern of a front electrode to be formed at a semiconductor substrate are formed at a printing substrate 300. At this time, a method of forming the grooves 301 is not particularly restricted. For example, the grooves 301 may be formed using a well-known method, such as photolithography. Subsequently, the interiors of the grooves 301 are filled with paste 310 for electrode formation. To this end, the paste 310 is applied to the surface of the printing substrate 300, and a doctor blade 330 is moved in a state in which the doctor blade 330 is in contact with the printing substrate 300. With the movement of the doctor blade 330, the interiors of the grooves 301 are filled with the paste 310. On the other hand, the remaining paste 310 may be removed from the printing substrate 300 by the doctor blade 330.

Subsequently, the paste 310 placed in the grooves 301 of the printing substrate 300 is transferred to the surface of a printing roll 340, which is rotated in a state in which the printing roll 340 is in contact with the printing substrate 300. The printing roll 340 may have the same width as a semiconductor substrate 204 at which a pattern is to be formed. Also, the printing roll 340 may have a circumference equal to the length of the semiconductor substrate 204. Consequently, all of the paste 310 placed in the grooves 301 of the printing substrate 300 is transferred to the circumferential surface of the printing roll 340 by a single rotation of the printing roll 340.

Subsequently, the printing roll 340 is rotated in a state in which the printing roll 340 is in contact with the surface of the semiconductor substrate 204. As a result, the paste 310 is transferred from the printing roll 340 to the semiconductor substrate 204. Subsequently, the paste transferred to the semiconductor substrate 204 is cured to form a pattern.

When the front electrode is patterned using the offset printing method as described above, it is possible to easily form a micrometer scale pattern. In addition, the printing substrate 300 and the printing roll 340 are manufactured so as to correspond to the size of the semiconductor substrate 204. Consequently, it is possible to form the pattern through a single transfer process, thereby greatly improving process efficiency.

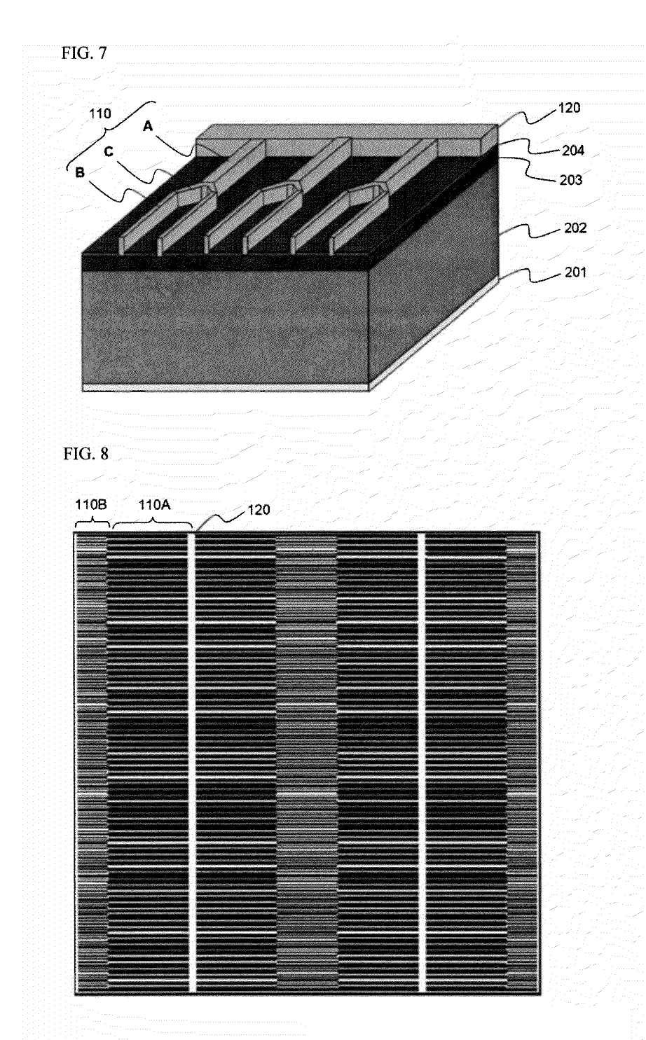

FIG. 7 is a partial perspective view typically illustrating a solar cell having the front electrode of FIG. 3.

Referring to FIG. 7, the solar cell include a p-type semiconductor layer 202 and an n-type semiconductor layer 203, which is opposite to the conduction type of the p-type semiconductor layer 202, formed on the p-type semiconductor layer 202. A p/n junction is achieved at the interface between the p-type semiconductor layer 202 and the n-type semiconductor layer 203. A rear electrode 201 is formed at the bottom of the p-type semiconductor layer 202. An anti-reflective film 204 having a honeycomb structure to disturb light reflection is formed at the top of the n-type semiconductor layer 203. A front electrode 110 including grid electrodes and a current collection electrode 120 is formed on the anti-reflective film 204 in a state in which the front electrode is in contact with at least a portion of the n-type semiconductor layer 203.

A p-type silicon substrate is usually used as the p-type semiconductor layer 202, and a phosphorous (P)-doped n-type emitter layer is used as the n-type semiconductor layer 203. Also, the front electrode 110 is usually formed of a silver (Ag) pattern, and the rear electrode 210 disposed at the bottom of the p-type semiconductor layer 202 is usually formed of an aluminum (Al) layer.

The front electrode includes a first pattern part 110A including grid electrodes perpendicularly connected to the current collection electrode 120, which has a large width, each of the grid electrodes having a width of 150 μm or less, a second pattern part 110B including grid electrodes having a smaller width than the grid electrodes of the first pattern part A, and dendrite electrodes 110C including grid electrodes interconnecting the grid electrodes of the first pattern part 110A and the grid electrodes of the second pattern part 110B.

In the above structure, the increase in resistance of current, introduced from the n-type semiconductor layer 203 to the second pattern part B, flowing in the grid electrodes 110 is minimized by the first pattern part A. In addition, the intervals of the grid electrodes at the first pattern part 110A are configured to be large, and the intervals of the grid electrodes at the second pattern part 110B are configured to be small, thereby minimizing power loss.

FIG. 8 is a plan view typically illustrating a front electrode of a solar cell according to the present invention.

Referring to FIG. 8, the front electrode is configured to have a structure in which grid electrodes are arranged between two current collection electrodes 120 so that the grid electrodes are perpendicular to the current collection electrodes 120. First pattern parts 110A having a relatively large thickness are connected to the respective current collection electrodes 120 so that the first pattern parts 110A are perpendicular to the current collection electrodes 120. Also, second pattern parts 110B are connected to the respective first pattern parts 110A. The first pattern parts 110A and the second pattern parts 110B are connected to each other in a middle portion defined between the two current collection electrodes 120.

Hereinafter, the present invention will be described in more detail with reference to the following examples. These examples are provided only for illustrating the present invention and should not be construed as limiting the scope of the present invention.

### Example 1

Phosphorous (P) was diffused on a crystalline p-type silicon substrate to form an n layer having a resistance of 50 ohm, and an anti-reflective silicon nitride (SiNx) layer was deposited at the front of the n layer. Aluminum (Al) paste was screen printed and hardened on the rear of the substrate having the p-n junction as described above to form a rear electrode layer, and an electrode was formed at the front of the n layer in the shape shown in FIG. 3 through an offset printing method using silver (Ag) paste. Specifically, grid electrodes of a first pattern part A were formed to have a length of 2.6 cm, and grid electrodes of a second pattern part B were formed to have a length of 1 cm. The grid electrodes of the first pattern part A were formed to have a width of 90 μm and intervals of 1 mm. Dendrite electrodes C were formed to have a length of 0.05 cm. A solar cell having a resistance of 50 ohm at the n layer was manufactured using the electrode formed as described above.

### Example 2

A solar cell having a resistance of 100 ohm at an n layer was manufactured using the same method as in Example 1 except that the grid electrodes of the first pattern part were formed to have a length of 2.4 cm, the grid electrodes of the second pattern part were formed to have a length of 1.2 cm, the grid electrodes of the first pattern part were formed to have a width of 20 μm and intervals of 0.83 mm, and the dendrite electrodes C were formed to have a length of 0.05 cm.

### Comparative Example 1

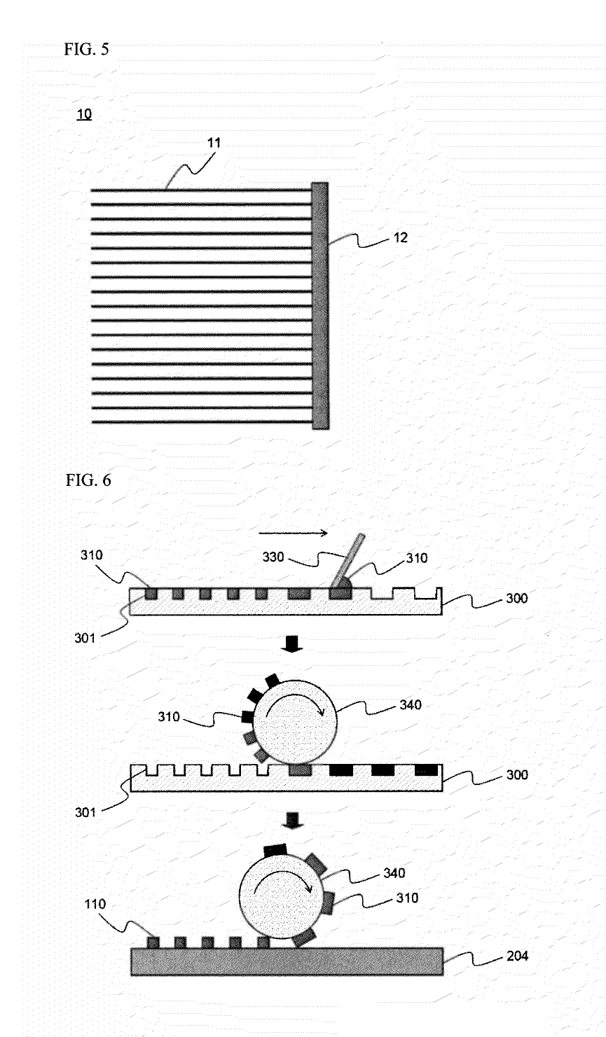

Grid electrodes were formed into a shape as shown in FIG. 5 to have a width of 120 μm and intervals of 2.5 mm, thereby manufacturing a solar cell having a resistance of 50 ohm at an n layer.

### Comparative Example 2

Grid electrodes were formed to have a width of 20 μm and intervals of 1 mm into a shape as shown in FIG. 5, thereby manufacturing a solar cell having a resistance of 50 ohm at an n layer.

### Comparative Example 3

Grid electrodes were formed into a shape as shown in FIG. 5 to have a width of 120 μm and intervals of 2.5 mm, thereby manufacturing a solar cell having a resistance of 100 ohm at an n layer.

### Comparative Example 4

Grid electrodes were formed to have a width of 20 μm and intervals of 1 mm into a shape as shown in FIG. 5, thereby manufacturing a solar cell having a resistance of 100 ohm at an n layer.

TABLE 1

| | Length of grid | | Width of grid | | Intervals of grid | | |
|---|---|---|---|---|---|---|---|
| | electrodes (cm) | | electrodes (μm) | | electrodes (mm) | | |
| | First | Second | First | Second | First | Second | Resistance |
| | pattern | pattern | pattern | pattern | pattern | pattern | of n layer |
| | part | part | part | part | part | part | (ohm) |
| Example 1 | 2.6 | 1.0 | 90 | 20 | 2 | 1 | 50 |
| Example 2 | 2.4 | 1.2 | 90 | 20 | 1.7 | 0.83 | 100 |

| | | | | |
|---|---|---|---|---|
| Comparative | 3.6 | 120 | 2.5 | 50 |
| example 1 | | | | |
| Comparative | 3.6 | 20 | 1 | 50 |
| example 2 | | | | |
| Comparative | 3.6 | 120 | 2.5 | 100 |
| example 3 | | | | |
| Comparative | 3.6 | 20 | 1 | 100 |
| example 4 | | | | |

### Experimental Example 1

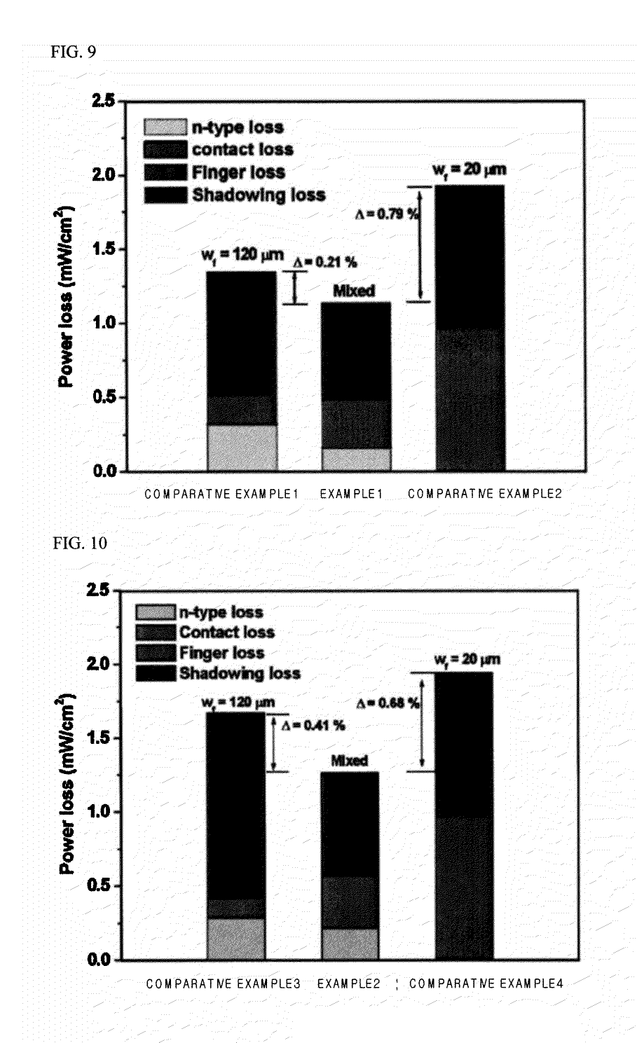

Power losses of the solar cells manufactured according to Examples 1 and 2 and Comparative examples 1 to 4 were calculated. The results are indicated in FIGS. 9 and 10 and Table 2 below.

TABLE 2

| | | | | | | Difference | Difference |
|---|---|---|---|---|---|---|---|
| | | | | | | of loss from | of loss from |
| | n-type | Contact | Finger | Shadow | Total | Comparative | Comparative |
| | loss | loss | loss | loss | loss | example 1 (3) | example 2 (4) |
| Example 1 | 0.16 | 0.003 | 0.31 | 0.67 | 1.14 | 0.21% | 0.79% |
| Example 2 | 0.21 | 0.003 | 0.35 | 0.70 | 1.26 | 0.41% | 0.68% |
| Comparative | 0/32 | 0.003 | 0.18 | 0.94 | 1.35 | — | — |
| example 1 | | | | | | | |
| Comparative | 0.007 | 0.005 | 0.95 | 0.98 | 1.93 | — | — |
| example 2 | | | | | | | |
| Comparative | 0.28 | 0.003 | 0.12 | 1.26 | 1.67 | — | — |
| example 3 | | | | | | | |
| Comparative | 0.01 | 0.0007 | 0.95 | 0.98 | 1.94 | — | — |
| example 4 | | | | | | | |

In Table 2, the n-type loss (loss I) is caused when current flows in the n-type semiconductor layer, the contact loss (loss II) is caused when the current flows from the n-type semiconductor layer to the grid electrodes, the finger loss (loss III) is caused when the current flows in the grid electrodes, and the shadow loss (loss IV) is caused by an area covered by the grid electrodes.

Also, in Table 2, the differences of loss between Examples and Comparative examples were based on the same resistance of the emitter (the same resistance of the n layer). That is, Example 1 was compared with Comparative examples 1 and 2 having an emitter resistance of 50 ohm, and Example 2 was compared with Comparative examples 3 and 4 having an emitter resistance of 50 ohm.

First, referring to FIG. 9 and Table 2, it can be seen that the power loss of the solar cell of Example 1 having the front electrode according to the present invention was much less than that of the solar cell of Comparative examples 1 and 2.

Specifically, it can be seen that, for the battery of Comparative example 2, the grid electrodes were excessively thin and arranged at small intervals, and therefore, the resistance of current flowing in the grid electrodes was increased with the result that loss III was very high, whereas loss III was greatly reduced for the battery of Example 1. Also, it can be seen that, for the battery of Comparative example 1, the grid electrodes had a large width and large intervals, and therefore, shadow loss was very high, whereas the shadow loss was greatly reduced for the battery of Example 1.

The power loss of the battery of Example 1 was 0.21% lower than that of battery of Comparative example 1 and 0.79% lower than that of battery of Comparative example 2.

Also, referring to FIG. 10 and Table 2, it can be seen that, when the n-type semiconductor layer having a resistance of 100 ohm was formed, power loss of the battery according to the present invention was much less (0.41% less) than that of the conventional battery (Comparative example 3). Consequently, it can be seen that the front electrode according to the present invention can be preferably applied to even in a case in which a high-resistance n-type semiconductor layer is used so as to reduce surface recombination velocity of current.

### INDUSTRIAL APPLICABILITY

As is apparent from the above description, the front electrode for solar cells according to the present invention is configured to have a structure in which the width of the grid electrodes is increased toward the current collection electrode, thereby minimizing the increase of resistance while minimizing shadow loss and thus reducing power loss. Consequently, it is possible to manufacture a solar cell exhibiting high efficiency.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A front electrode for solar cells, wherein the front electrode is configured in a structure in which a pattern comprising a plurality of grid electrodes arranged in parallel and at least one current collection electrode intersecting the grid electrodes is formed on a semiconductor substrate, current introduced to the grid electrodes is moved to and collected in the current collection electrode, and the width of each of the grid electrodes is increased toward the current collection electrode.

2. The front electrode for solar cells according to claim 1, wherein the grid electrodes are at right angles to the current collection electrode.

3. The front electrode for solar cells according to claim 1, wherein the width of each of the grid electrodes is continuously increased in inverse proportion to the distance from the current collection electrode.

4. The front electrode for solar cells according to claim 1, wherein the width of each of the grid electrodes is discontinuously increased in inverse proportion to the distance from the current collection electrode.

5. The front electrode for solar cells according to claim 1, wherein the width of each of the grid electrodes is increased so that the width of each of the grid electrodes at one end thereof adjacent to the current collection electrode is 50 to 500% greater than the width of each of the grid electrodes at the other end thereof distant from the current collection electrode.

6. The front electrode for solar cells according to claim 4, wherein the pattern comprises a first pattern part at which the width of each of the grid electrodes is 150 μm or less and a second pattern part at which the width of each of the grid electrodes is less than that of each of the grid electrodes at the first pattern part.

7. The front electrode for solar cells according to claim 6, wherein the second pattern part is configured to have a structure in which two or more grid electrodes are joined to each other.

8. The front electrode for solar cells according to claim 6, wherein dendrite electrodes are located between the grid electrodes of the first pattern part and the grid electrodes of the second pattern part to interconnect the grid electrodes of the first pattern part and the grid electrodes of the second pattern part.

9. The front electrode for solar cells according to claim 8, wherein the width of each of the dendrite electrodes is one to two times that of each of the grid electrodes of the second pattern part.

10. The front electrode for solar cells according to claim 8, wherein the width of each of the grid electrodes of the first pattern part is 1.1 to 15 times that of each of the grid electrodes of the second pattern part within a range greater than that of each of the dendrite electrodes.

11. The front electrode for solar cells according to claim 8, wherein the width of each of the grid electrodes of the second pattern part is 10 to 60 μm the width of each of the grid electrodes of the first pattern part is 50 to 150 μm within a range greater than that of each of the grid electrodes of the second pattern part, and the width of each of the dendrite electrodes is equal to that of each of the grid electrodes of the second pattern part or 10 to 60 μm within a range greater than that of each of the grid electrodes of the second pattern part.

12. The front electrode for solar cells according to claim 6, wherein the intervals of the grid electrodes of the first pattern part are 0.7 to 6 times those of the grid electrodes of the second pattern part.

13. The front electrode for solar cells according to claim 6, wherein the intervals of the grid electrodes of the second pattern part are 0.5 to 2 mm, and the intervals of the grid electrodes of the first pattern part are equal to those of the grid electrodes of the second pattern part or 1.5 to 3 mm within a range greater than those of the grid electrodes of the second pattern part.

14. The front electrode for solar cells according to claim 8, wherein the length of each of the grid electrodes of the second pattern part is 10 to 70% the total length of each of the grid electrodes, the length of each of the grid electrodes of the first pattern part is 30 to 90% the total length of each of the grid electrodes, and the length of each of the dendrite electrodes is 0 to 10% the total length of each of the grid electrodes.

15. The front electrode for solar cells according to claim 1, wherein the semiconductor substrate comprises an n-type semiconductor layer formed of crystalline silicon.

16. The front electrode for solar cells according to claim 1, wherein the semiconductor substrate has a resistance of 50Ω or more.

17. A solar cell comprising a front electrode according to claim 1, wherein the solar cell has an electrode loss of 1.3 mW/cm².

18. A method of manufacturing a front electrode for solar cells according to claim 1, wherein, upon forming a pattern comprising a plurality of grid electrodes arranged in parallel and a current collection electrode intersecting the grid electrodes on a semiconductor substrate, the method comprises:
(a) printing paste on a semiconductor substrate using a gravure printing method or an offset printing method so that the grid electrodes have a width of 100 μm or less; and
(b) heating and/or pressurizing the paste to harden the paste.

19. The method according to claim 18, wherein the offset printing method comprises: preparing a printing substrate having grooves formed in a predetermined pattern corresponding to that of the front electrode; filling the grooves formed at the printing substrate with paste for electrode formation; rotating a printing roll on the printing substrate to transfer the paste placed in the grooves to the printing roll; and rotating the printing roll on a semiconductor substrate to transfer the paste from the printing roll to the semiconductor substrate.

20. The method according to claim 18, wherein the gravure printing method comprises: preparing a blanket cylinder having grooves formed in a predetermined pattern corresponding to that of the front electrode; filling the grooves formed at the blanket cylinder with paste for electrode formation; and rotating the blanket cylinder on a semiconductor substrate to transfer the paste from the blanket cylinder to the semiconductor substrate.

21. The method according to claim 18, wherein the paste contains silver (Ag) powder.
